(19) United States
(12) Patent Application Publication
(10) Pub. No.: US 2024/0431132 A1
(43) Pub. Date: Dec. 26, 2024

(54) DISPLAY DEVICE

(71) Applicant: Samsung Display Co., LTD., Yongin-si (KR)

(72) Inventors: Hee Woon IM, Yongin-si (KR); Yool Guk KIM, Yongin-si (KR); Ji Yoon KIM, Yongin-si (KR); Hyeon Sik KIM, Yongin-si (KR); Sang Ho LEE, Yongin-si (KR)

(21) Appl. No.: 18/413,983

(22) Filed: Jan. 16, 2024

(30) Foreign Application Priority Data
Jun. 20, 2023 (KR) 10-2023-0078859

(51) Int. Cl. H10K 50/115; H10K 50/16; H10K 59/122; H10K 59/80

(52) U.S. Cl. CPC H10K 50/115; H10K 50/16; H10K 59/122; H10K 59/873

(57) ABSTRACT

A display device includes a first substrate including an emission area and a non-emission area; a first pixel electrode positioned on the emission area of the first substrate; a first light emitting structure positioned on the first pixel electrode and including quantum dots; a pixel defining layer positioned on the non-emission area of the first substrate and positioned on the first pixel electrode; a common electrode covering the first light emitting structure and the pixel defining layer; and an encapsulation structure positioned on the common electrode and in contact with the common electrode such that the encapsulation structure overlaps the non-emission area. The encapsulation structure may include a second substrate and a hydrogen donor layer positioned between the second substrate and the common electrode. The hydrogen donor layer may overlap the emission area and may be in contact with or spaced apart from the common electrode.

### CROSS-REFERENCE TO RELATED APPLICATION

This application No. This application claims priority to Korean Patent 10-2023-0078859, filed on Jun. 20, 2023, and all the benefits accruing therefrom under 35 U.S.C. § 119, the content of which in its entirety is herein incorporated by reference.

### BACKGROUND

### 1. Technical Field

The present disclosure relates to a display device.

### 2. Description of the Related Art

With the development of the information society, the demand for display devices for displaying images has increased and diversified. For example, display devices have been applied to various electronic devices such as, for example, smartphones, digital cameras, laptop computers, navigation devices, and smart televisions.

Some display devices may be flat panel display devices such as, for example, liquid crystal display devices, field emission display devices, or light emitting display devices. The light emitting display devices may include organic light emitting display devices including organic light emitting elements and inorganic light emitting display devices including inorganic light emitting elements such as, for example, quantum dots.

Among them, development of display devices including the quantum dots has been conducted, and efforts to improve efficiency of display devices using the quantum dots have been continuously conducted.

### SUMMARY

Aspects of the present disclosure provide a display device in which efficiency of light emitting elements including quantum dots is improved.

Aspects of the present disclosure also provide a display device in which mass productivity of light emitting elements including quantum dots is improved.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

In an embodiment of the disclosure, a display device includes a first substrate including an emission area and a non-emission area; a first pixel electrode positioned on the emission area of the first substrate; a first light emitting structure positioned on the first pixel electrode and including quantum dots; a pixel defining layer positioned on the non-emission area of the first substrate and positioned on the first pixel electrode; a common electrode covering the first light emitting structure and the pixel defining layer; and an encapsulation structure positioned on the common electrode and in contact with the common electrode such that the encapsulation structure overlaps the non-emission area, wherein the encapsulation structure includes a second substrate and a hydrogen donor layer positioned between the second substrate and the common electrode, and the hydrogen donor layer overlaps the emission area and is in contact with the common electrode or is spaced apart from the common electrode with a space interposed between the hydrogen donor layer and the common electrode.

In an embodiment, the hydrogen donor layer may include a first portion overlapping the non-emission area and a second portion overlapping the emission area, and the first portion is in contact with the common electrode.

In an embodiment, the first portion and the second portion of the hydrogen donor layer may extend in a direction parallel to the substrate.

In an embodiment, the hydrogen donor layer may include at least one of silicon nitride and silicon oxide.

In an embodiment, the hydrogen donor layer may further include hydrogen forming any one of a silicon-hydrogen (Si—H) bond, a nitrogen-hydrogen (N—H) bond, and an oxygen-hydrogen (O—H) bond.

In an embodiment, the spaces may be surrounded by the non-emission area in a plan view.

In an embodiment, first light emitting structure may include a quantum dot light emitting layer and an electron transport layer, and the first light emitting structure includes an inclined part inclined in a direction toward the common electrode at a portion of the inclined part in contact with the pixel defining layer.

In an embodiment, the inclined part may overlap the hydrogen donor layer.

In an embodiment, the electron transport layer may include zinc oxide.

In an embodiment, a portion of the second substrate overlapping the non-emission area may be in contact with the common electrode.

In an embodiment, the hydrogen donor layer may be positioned within the space.

In an embodiment, the hydrogen donor layer may do not overlap the non-emission area.

In an embodiment, a display device includes a second pixel electrode spaced apart from the first pixel electrode with the pixel defining layer interposed between the second pixel electrode spaced and the first pixel electrode; a second light emitting structure positioned on the second pixel electrode; and a second hydrogen donor layer positioned on the second light emitting structure, wherein the hydrogen donor layer overlaps the first light emitting structure, the hydrogen donor layer overlaps the second light emitting structure, and the hydrogen donor layer and the second hydrogen donor layer may be spaced apart from each other.

In an embodiment, the hydrogen donor layer may be surrounded by the space in a plan view, and the second hydrogen donor layer may be surrounded by a second space in the plan view.

In an embodiment, the space overlapping the first light emitting structure and the second space overlapping the second light emitting structure may be spaced apart from each other in the plan view.

In an embodiment of the disclosure, a display device includes a first substrate including an emission area and a non-emission area; a first pixel electrode positioned on the emission area of the first substrate; a light emitting structure positioned on the first pixel electrode and including quantum dots; a pixel defining layer positioned on the non-emission area of the first substrate and including a recessed part; a common electrode covering the light emitting structure and the pixel defining layer; and an encapsulation structure positioned on the common electrode and in contact with the common electrode such that the encapsulation structure overlaps the non-emission area, wherein the encapsulation structure includes a second substrate and a hydrogen donor layer positioned between the second substrate and the common electrode, and the hydrogen donor layer overlaps the recessed part of the pixel defining layer.

In an embodiment, the hydrogen donor layer may include a first surface facing the first substrate; and a second surface opposing the first surface, and a width of the second surface may be greater than a width of the first surface.

In an embodiment, a portion of the second substrate overlapping the emission area may be spaced apart from the common electrode with a space interposed therebetween.

In an embodiment, the hydrogen donor layer may surround the space in the plan view.

In an embodiment, a display device may further comprise a second pixel electrode spaced apart from the first pixel electrode with the pixel defining layer interposed between the second pixel electrode and the first pixel electrode; and a second light emitting structure positioned on the second pixel electrode, wherein the hydrogen donor layer may be positioned between the first light emitting structure and the second light emitting structure.

With reference to a display device according to one or more of the embodiments described herein, it is possible to improve efficiency of light emitting elements including quantum dots by providing inorganic films including hydrogen on the light emitting elements.

The effects of the present disclosure are not limited to the aforementioned effects, and various other effects are included in the present specification.

### BRIEF DESCRIPTION OF THE DRAWINGS

These and/or other features will become apparent and more readily appreciated from the following description of the embodiments, taken in conjunction with the accompanying drawings in which:

FIG. 1 is a perspective view illustrating a display device according to an embodiment;

FIG. 2 is a plan view of the display device according to an embodiment;

FIG. 3 is a cross-sectional view of a display panel taken along line I-I′ of FIG. 2;

FIG. 4 is an enlarged plan view of area ‘A’ of FIG. 2;

FIG. 5 is a cross-sectional view of the display device taken along line X1-X1′ of FIG. 4;

FIG. 6 is an enlarged cross-sectional view of a first emission area of the display device of FIG. 5;

FIG. 7 is a cross-sectional view illustrating a hydrogen movement path of the display device of FIG. 6;

FIG. 8 is an enlarged plan view of area ‘A’ of FIG. 2 according to another embodiment;

FIG. 9 is a cross-sectional view of the display device taken along line X3-X3′ of FIG. 8;

FIG. 10 is an enlarged cross-sectional view of a first emission area of the display device of FIG. 8;

FIG. 11 is an enlarged plan view of area ‘A’ of FIG. 2 according to still another embodiment;

FIG. 12 is a cross-sectional view of the display device taken along line X5-X5′ of FIG. 11; and

FIG. 13 is an enlarged cross-sectional view of a first emission area of the display device of FIG. 12.

### DETAILED DESCRIPTION

Hereinafter, illustrative embodiments will be described with reference to the accompanying drawings.

It will be understood that, although the terms “first,” “second,” “third” etc. may be used herein to describe various elements, components, regions, layers and/or sections, these elements, components, regions, layers and/or sections should not be limited by these terms. These terms are used to distinguish one element, component, region, layer or section from another element, component, region, layer or section and are not to be limited. Thus, “a first element,” “component,” “region,” “layer” or “section” discussed below could be termed a second element, component, region, layer or section without departing from the teachings herein.

The terminology used herein is for the purpose of describing example embodiments and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top.” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The example term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The example terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within #30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

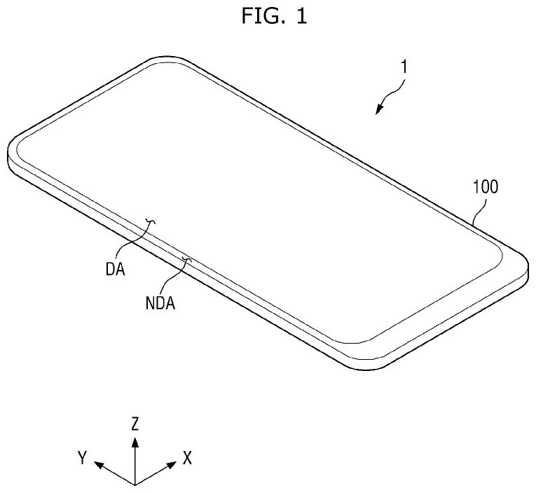

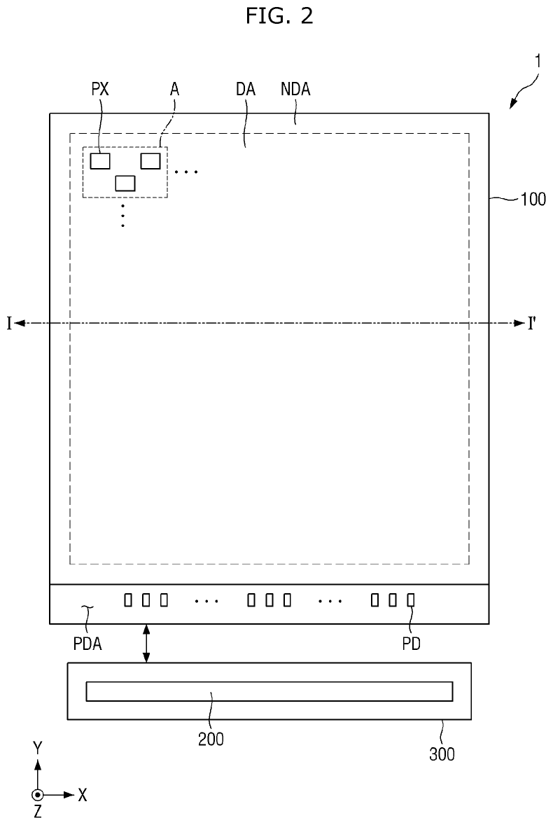

FIG. 1 is a perspective view illustrating a display device according to an embodiment. FIG. 2 is a plan view of the display device according to an embodiment.

Referring to FIG. 1, a display device 1 displays a moving image or a still image. The display device 1 may refer to all electronic devices that provide display screens. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, which provide display screens, may be included in the display device 1.

Examples of the display device 1 may include an inorganic light emitting diode display device, an organic light emitting display device, a quantum dot light emitting display device, a plasma display device, a field emission display device, and the like. Hereinafter, a case where an inorganic light emitting diode display device is applied as an example of the display device will be described by way of example, but the present disclosure is not limited thereto, and the same technical spirit may be applied to other display devices if applicable.

A shape of the display device 1 may be variously modified. For example, the display device 1 may have a shape such as, for example, a rectangular shape with a width greater than a length, a rectangular shape with a length greater than a width, a square shape, a rectangular shape with rounded corners (vertices), other polygonal shapes, or a circular shape. A shape of a display area DA of the display device 1 may also be similar to an overall shape of the display device 1. In FIG. 1, the display device 1 having a rectangular shape with a great length in a second direction Y is illustrated, but the present disclosure is not limited thereto.

Referring to FIGS. 1 and 2, the display device 1 may include a display panel 100, a display driver 200, and a circuit board 300.

The display panel 100 may be formed in a rectangular shape, in a plan view, having short sides in a first direction (X-axis direction) and long sides in a second direction (Y-axis direction) crossing the first direction (X-axis direction). A corner where the short side in the first direction (X-axis direction) and the long side in the second direction (Y-axis direction) meet may be rounded with a predetermined curvature or right-angled. The shape of the display panel 100 in a plan view is not limited to the rectangular shape, and may be other polygonal shapes, a circular shape, or an elliptical shape. The display panel 100 may be formed to be flat, but is not limited thereto, and may include curved surface parts formed at left and right ends of the display panel 100 and having a constant curvature or a variable curvature. In one or more embodiments, the display panel 100 may be flexibly formed to be curved, bent, folded, or rolled.

The display panel 100 may include a display area DA, a non-display area NDA, and a pad area PDA.

The display area DA may occupy substantially the center of the display device 1. A plurality of pixels PX may be disposed in the display area DA. Each of the plurality of pixels PX may be defined as a minimum unit emitting light. The plurality of pixels PX may be connected to signal lines positioned in the non-display area NDA. The display area DA may emit light from emission areas EA or a plurality of openings OP included in the plurality of pixels PX.

The non-display area NDA may be an area outside the display area DA. The non-display area NDA may surround the display area DA at an edge area of the display panel 100. The non-display area NDA may include a gate driver (not illustrated) supplying gate signals to gate lines, fan-out lines (not illustrated) connecting the display driver 200 and the display area DA to each other, and the like.

The display driver 200 may output signals and voltages for driving the display panel 100. The display driver 200 may supply data voltages to data lines. The display driver 200 may supply source voltages to power lines and supply gate control signals to the gate driver. The display driver 200 may be formed as an integrated circuit (IC) and mounted on the display panel 100 in a chip on glass (COG) manner, a chip on plastic (COP) manner, or an ultrasonic bonding manner.

The circuit board 300 may be attached onto pad parts of the display panel 100 using an anisotropic conductive film (ACF). Lead lines of the circuit board 300 may be electrically connected to the pad parts of the display panel 100. The circuit board 300 may be a flexible printed circuit board, a printed circuit board, or a flexible film such as, for example, a chip on film.

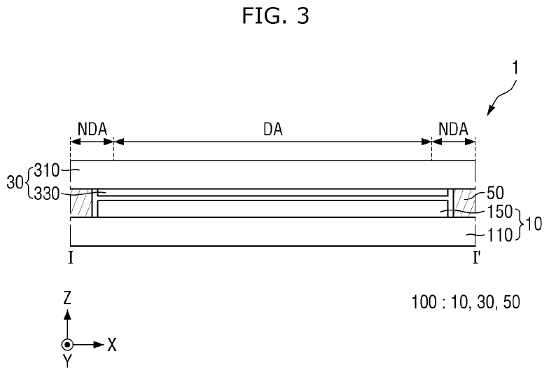

A plurality of display pads PD may be disposed in the pad area PDA. The plurality of display pads PD may be disposed at an edge of the pad area PDA. The plurality of display pads PD may be connected to a graphic system through the circuit board 300. The plurality of display pads PD may be connected to the circuit board 300 to receive digital video data, and may supply the digital video data to the display driver 200. FIG. 3 is a cross-sectional view of a display panel taken along line I-I′ of FIG. 2.

A schematic stacked structure of the display device 1 in accordance with one or more embodiments of the present disclosure will be described with reference to FIG. 3. The display device 1 may include a first substrate 10, a second substrate 30 facing the first substrate 10, and a sealing part 50 coupling the first substrate 10 and the second substrate 30 to each other. In one or more embodiments, the first substrate 10 may include a first base substrate 110 and a light emitting element layer 150, and the second substrate 30 may include a second base substrate 310 and a hydrogen donor layer 330.

The first base substrate 110 may be a base substrate or a base member. The first base substrate 110 may be a flexible substrate that may be bent, folded, or rolled. As an example, the first base substrate 110 may include a polymer resin such as, for example, polyimide (PI), but is not limited thereto. As another example, the first base substrate 110 may include a glass material or a metal material.

The light emitting element layer 150 may include pixel circuits including switching elements, a pixel defining film defining emission areas or opening areas, and self-light emitting elements. For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto.

The second base substrate 310 may be formed of various materials such as, for example, glass, a metal, or plastic such as, for example, polyethylene terephthalate (PET), polyethylene naphthalate (PEN), or polyimide. In one or more embodiments, the second substrate 30 may include ultra thin glass (UTG) having a thickness of 0.01 mm or less. The second substrate 30 may prevent impurities such as, for example, moisture or air from permeating from the outside (e.g., outside the display panel 100) and being diffused into the light emitting element layer 150 of the first substrate 10.

The hydrogen donor layer 330 may be positioned on the second base substrate 310. The hydrogen donor layer 330 may be deposited on the second base substrate 310, and may be then bonded to the first substrate 10 via the sealing part 50 through a subsequent process. The hydrogen donor layer 330 may be positioned between the first base substrate 110 and the second base substrate 310. In one or more embodiments, the hydrogen donor layer 330 may be positioned such that the hydrogen donor layer 330 overlaps the light emitting element layer 150.

The hydrogen donor layer 330 may be an inorganic layer including silicon. As an example, the hydrogen donor layer 330 may include silicon oxide (SiO₂), silicon nitride (Si₃N₄), and silicon oxynitride (Si₂N₂O). In some examples, the hydrogen donor layer 330 may include one or more of silicon oxide (SiO₂), silicon nitride (Si₃N₄), and silicon oxynitride (Si₂N₂O).

The sealing part 50 may overlap the non-display area NDA and be disposed along edges of the first substrate 10 and the second substrate 30 such that the sealing part 50 surrounds the display area DA in a plan view. The first substrate 10 and the second substrate 30 may be coupled to each other via the sealing part 50. The sealing part 30 may prevent impurities such as, for example, moisture or air from permeating from the outside and being diffused into the light emitting element layer 150 of the first substrate 10. The sealing unit 50 may include both an organic material based on an epoxy-based resin and an inorganic material based on a glass component.

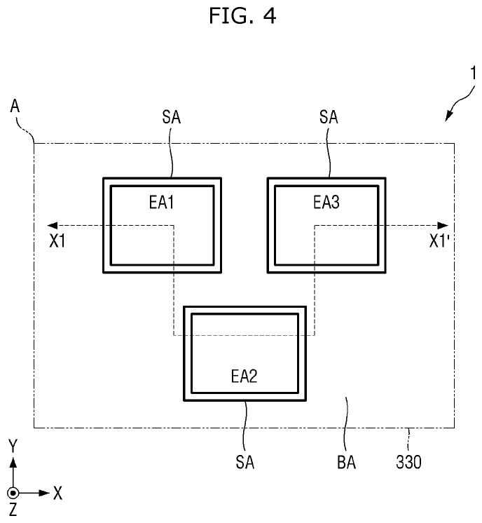

FIG. 4 is an enlarged plan view of area ‘A’ of FIG. 2.

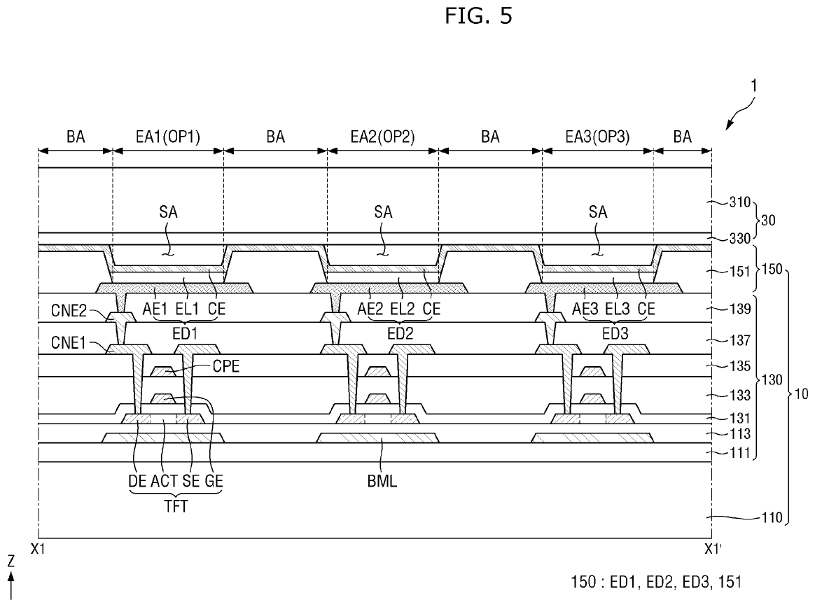

Referring to FIG. 4, the display device 1 in accordance with one or more embodiments of the present disclosure may include a plurality of emission areas EA1, EA2, and EA3 disposed in the display area DA. The emission areas EA1, EA2, and EA3 may include a first emission area EA1, a second emission area EA2, and a third emission area EA3 capable of emitting light of different colors. The emission areas EA1, EA2, and EA3 may emit red, green, or blue light, respectively, and colors and wavelengths of the light emitted from the respective emission areas EA1, EA2, and EA3 may be different based on the types of light emitting elements ED1, ED2, and ED3 (see FIG. 5) respectively disposed at the light emitting element layer 150 in the emission areas EA1, EA2, and EA3. In an embodiment, the first emission area EA1 may emit first light, which is red light, the second emission area EA2 may emit second light, which is green light, and the third emission area EA3 may emit third light, which is blue light.

A non-emission area BA may be an area surrounding the emission areas EA1, EA2, and EA3. The non-emission area BA may be an area through which light does not pass, but is not limited thereto. For example, the non-emission area BA may be opaque or partially opaque. In some examples, the amount of light which may or may not pass through the non-emission area BA may be based on a material included in a pixel defining layer 151 (see FIG. 5) to be described later.

In some embodiments, the display device 1 may include spaces SA respectively surrounding the emission areas EA1, EA2, and EA3. The spaces SA may be caused by bonding between the first substrate 10 and the second substrate 30. For example, the spaces SA may be formed during a bonding process between the first substrate 10 and the second substrate 30. The spaces SA may be filled with a nitrogen gas (N₂) or air according to the atmosphere of a manufacturing process. The spaces SA will be described later in detail.

In some embodiments, the hydrogen donor layer 330 may cover all of the emission areas EA1, EA2, and EA3, the spaces SA, and the non-emission area BA.

FIG. 5 is a cross-sectional view of the display device 1 taken along line X1-X1′ of FIG. 4.

Referring to FIG. 5, the first substrate 10 of the display device 1 may include a first base substrate 110, a thin film transistor layer 130, and a light emitting element layer 150. The thin film transistor layer 130 may be positioned on the first base substrate 110.

The term “positioned on” may refer to forming or disposing an element, for example, directly or indirectly on another element, directly or indirectly under another element, or adjacent another element.

The thin film transistor layer 130 may include a first buffer layer 111, a bottom metal layer BML, a second buffer layer 113, thin film transistors TFT, a gate insulating layer 131, a first interlayer insulating layer 133, capacitor electrodes CPE, a second interlayer insulating layer 135, first connection electrodes CNE1, a first passivation layer 137, second connection electrodes CNE2, and a second passivation layer 139.

The first buffer layer 111 may be disposed on the first base substrate 110. The first buffer layer 111 may include an inorganic film capable of preventing permeation of air or moisture. For example, the first buffer layer 111 may include a plurality of inorganic films that are alternately stacked.

The bottom metal layer BML may be disposed on the first buffer layer 111. For example, the bottom metal layer BML may be formed as a single layer or multiple layers of any one of molybdenum (Mo), aluminum (Al), chromium (Cr), gold (Au), titanium (Ti), nickel (Ni), neodymium (Nd), and copper (Cu), or alloys thereof.

The second buffer layer 113 may cover the first buffer layer 111 and the bottom metal layer BML. The second buffer layer 113 may include an inorganic film capable of preventing permeation of air or moisture. For example, the second buffer layer 113 may include a plurality of inorganic films that are alternately stacked.

The thin film transistor TFT may be disposed on the second buffer layer 113 and may constitute a pixel circuit of each of the plurality of pixels. The thin film transistor TFT may be a driving transistor or a switching transistor of the pixel circuit. The thin film transistor TFT may include a semiconductor layer ACT, a source electrode SE, a drain electrode DE, and a gate electrode GE. The thin film transistor TFT may include an oxide thin film transistor (Oxide TFT) and, in some examples, a low temperature polysilicon thin film transistor (LTPS).

The semiconductor layer ACT may be disposed on the second buffer layer 113. The semiconductor layer ACT may overlap the bottom metal layer BML and the gate electrode GE in a thickness direction, and the semiconductor layer ACT may be insulated from the gate electrode GE by the gate insulating layer 131. A material of the semiconductor layer ACT in portions of the semiconductor layer ACT may be conductive. For example, material of the semiconductor layer ACT in portions of the semiconductor layer ACT may become conductors to form the source electrode SE and the drain electrode DE.

The gate electrode GE may be disposed on the gate insulating layer 131. The gate electrode GE may overlap the semiconductor layer ACT, with the gate insulating layer 131 interposed between the gate electrode GE and the semiconductor layer ACT.

The gate insulating layer 131 may be disposed on the semiconductor layer ACT.

For example, the gate insulating layer 131 may cover the semiconductor layer ACT and the second buffer layer 113, and the gate insulating layer 131 may insulate the semiconductor layer ACT and the gate electrode GE from each other. The gate insulating layer 131 may include contact holes through which the first connection electrodes CNE1 penetrate.

The first interlayer insulating layer 133 may cover the gate electrodes GE and the gate insulating layer 131. The first interlayer insulating layer 131 may include contact holes through which the first connection electrodes CNE1 penetrate. The contact holes of the first interlayer insulating layer 133 may be connected to the contact holes of the gate insulating layer 131 and contact holes of the second interlayer insulating layer 135.

The capacitor electrodes CPE may be disposed on the first interlayer insulating layer 133. The capacitor electrode CPE may overlap the gate electrode GE in the thickness direction. The capacitor electrode CPE and the gate electrode GE may form capacitance.

The second interlayer insulating layer 135 may cover the capacitor electrodes CPE and the first interlayer insulating layer 133. The second interlayer insulating layer 135 may include contact holes through which the first connection electrodes CNE1 penetrate. The contact holes of the second interlayer insulating layer 135 may be connected to the contact holes of the first interlayer insulating layer 133 and the contact holes of the gate insulating layer 131.

The first connection electrodes CNE1 may be disposed on the second interlayer insulating layer 135. The first connection electrode CNE1 may electrically connect the drain electrode DE of the thin film transistor TFT and the second connection electrode CNE2 to each other. The first connection electrode CNE1 may be inserted into the contact holes formed in the second interlayer insulating layer 135, the first interlayer insulating layer 133, and the gate insulating layer 131 to be in contact with the drain electrode DE of the thin film transistor TFT.

The first passivation layer 137 may cover the first connection electrodes CNE1 and the second interlayer insulating layer 135. The first passivation layer 137 may protect the thin film transistors TFT. The first passivation layer 137 may include contact holes through which the second connection electrodes CNE2 penetrate.

The second connection electrodes CNE2 may be disposed on the first passivation layer 137. The second connection electrodes CNE2 may electrically connect the first connection electrodes CNE1 and pixel electrodes AE1, AE2, and AE3 of light emitting elements ED1, ED2, and ED3 to each other. In an example, each second connection electrode CNE2 may be inserted into a contact hole formed in the first passivation layer 137 such that the second connection electrode CNE2 is in contact with a respective first connection electrode CNE1.

The second passivation layer 139 may cover the second connection electrodes CNE2 and the first passivation layer 137. The second passivation layer PAS2 may include contact holes through which the pixel electrodes AE1, AE2, and AE3 of the light emitting elements ED1, ED2, and ED3 penetrate.

The light emitting element layer 150 may be disposed on the thin film transistor layer 130. The light emitting element layer 150 may include the light emitting elements ED1, ED2, and ED3 and a pixel defining layer 151. In one or more embodiments, the light emitting elements ED1, ED2, and ED3 may each include the common electrode CE and may respectively include the pixel electrodes AE1, AE2, and AE3 and light emitting structures EL1, EL2, and EL3.

The display device 1 may include the plurality of emission areas EA1, EA2, and EA3. Each of the emission areas EA1, EA2, and EA3 may be defined by first to third openings OP1, OP2 OP3 defined by the pixel defining layer 151.

The light emitting elements ED1, ED2, and ED3 may include a first light emitting element ED1 disposed in the first emission area EA1, a second light emitting element ED2 disposed in the second emission area EA2, and a third light emitting element ED3 disposed in the third emission area EA3. The light emitting elements ED1, ED2, and ED3 may emit light of different colors based on materials of the light emitting structures EL1, EL2, and EL3. For example, the first light emitting element ED1 disposed in the first emission area EA1 may emit red light, which is light of a first color, the second light emitting element ED2 disposed in the second emission area EA2 may emit green light, which is light of a second color, and the third light emitting element ED3 disposed in the third emission area EA3 may emit blue light, which is light of a third color. The emission areas EA1, EA2, and EA3 constituting one pixel may include the light emitting elements ED1, ED2, and ED3 emitting the light of the different colors to express a white gradation. For example, a pixel including light emitting elements ED1, ED2, and ED3 may be capable of emitting white light.

The pixel electrodes AE1, AE2, and AE3 may be disposed on the second passivation layer 139. The pixel electrodes AE1, AE2, and AE3 may be electrically connected to the drain electrodes DE of the thin film transistors TFT through the first connection electrodes CNE1 and the second connection electrodes CNE2. For example, a pixel electrode (e.g., pixel electrode AE1) may be electrically connected to the drain electrode DE of a given thin film transistor TFT through the first connection electrode CNE1 and the second connection electrode CNE2 of the thin film transistor TFT. The pixel electrodes AE1, AE2, and AE3 may be disposed in the plurality of emission areas EA1, EA2, and EA3, respectively.

The pixel electrodes AE1, AE2, and AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2, and the third pixel electrode AE3 may respectively be disposed on the second passivation layer 139, such that the first pixel electrode AE1, the second pixel electrode AE2, and the third pixel electrode AE3 are spaced apart from each other on the second passivation layer 139.

Each of the pixel electrodes AE1, AE2, and AE3 may include indium tin oxide (ITO), indium zinc oxide (IZO), zinc oxide (ZnO), indium oxide (In₂O₃), or the like, and include a material layer that is transparent and has a high work function (e.g., above a threshold work function). In one or more embodiments, the pixel electrodes AE1, AE2, and AE3 are reflective electrodes, and the pixel electrodes AE1, AE2, and AE3 may have a stacked structure in which a layer formed of the material having the high work function described herein and a layer formed of a reflective material such as, for example, silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), or mixtures thereof are stacked. For example, one or more of the pixel electrodes AE1, AE2, and AE3 may have a multilayer structure of ITO/Mg, ITO/MgF, ITO/Ag, and ITO/Ag/ITO, but are not limited thereto.

The display device 1 may include the pixel defining layer 151 disposed on the second passivation layer 139 and the pixel electrodes AE1, AE2, and AE3. The pixel defining layer 151 may define a plurality of openings OP1, OP2, and OP3 forming the emission areas EA1, EA2, and EA3. The pixel defining layer 151 may be entirely disposed on the second passivation layer 139, and portions of the pixel defining layer 151 may expose upper surfaces of the pixel electrodes AE1, AE2, and AE3. In some embodiments, as illustrated in the example of FIG. 5, portions of the pixel defining layer 151 may expose portions of the upper surfaces of the pixel electrodes AE1, AE2, and AE3. The pixel defining layer 151 may include an organic insulating material such as, for example, a polyacrylates resin, an epoxy resin, a phenolic resin, a polyamides resin, a polyimides resin, an unsaturated polyesters resin, a polyphenylene ethers resin, a polyphenylene sulfides resin, or benzocyclobutene (BCB).

The light emitting structures EL1, EL2, and EL3 may be disposed on the pixel electrodes AE1, AE2, and AE3, respectively. When the thin film transistors TFT apply a predetermined voltage to the pixel electrodes AE1, AE2, and AE3 of the light emitting elements ED1, ED2, and ED3 and the common electrode CE of the light emitting elements ED1, ED2, and ED3 receives a common voltage or a cathode voltage, the light emitting structures EL1, EL2, and EL3 of the light emitting elements ED1, ED2, and ED3 may emit light.

The light emitting structures EL1, EL2, and EL3 may include a first light emitting structure EL1, a second light emitting structure EL2, and a third light emitting structure EL3 disposed in different emission areas EA1, EA2, and EA3, respectively. The first light emitting structure EL1 may be disposed on the first pixel electrode AE1 in the first emission area EA1, the second light emitting structure EL2 may be disposed on the second pixel electrode AE2 in the second emission area EA2, and the third light emitting structure EL3 may be disposed on the third pixel electrode AE3 in the third emission area EA3. The light emitting structures EL1, EL2, and EL3 included in the display device 1 may include quantum dots, which will be described in detail later.

The common electrode CE may be disposed on the light emitting structures EL1, EL2, and EL3. The common electrode CE may be positioned such that the common electrode CE covers the light emitting structures EL1, EL2, and EL3 positioned in the respective emission areas EA1, EA2, and EA3 and the pixel defining layer 151. In some embodiments, in the example illustrated at FIG. 5, the common electrode CE may continuously extend across the emission areas EA1, EA2, and EA3 and the emission area EA1, EA2, and EA3. The common electrode CE may include a transparent conductive material to emit the light generated from the light emitting structures EL1, EL2, and EL3. In some embodiments, the transparent conductive material may be a transparent conductive metal layer.

The common electrode CE may receive the common voltage or a low potential voltage. When the pixel electrodes AE1, AE2, and AE3 receive a voltage corresponding to a data voltage and the common electrode CE receives a low potential voltage, potential differences are formed between the pixel electrodes AE1, AE2, and AE3 and the common electrode CE, such that the light emitting structures EL1, EL2, and EL3 may emit light based on the potential differences. The common electrode CE may include a material layer having a small work function (e.g., below a threshold work function), such as, for example, Li, Ca, LiF/Ca, LiF/Al, Al, Mg, Ag, Pt, Pd, Ni, Au, Nd, Ir, Cr, BaF, Ba, or compounds or mixtures thereof (e.g., a mixture of Ag and Mg, etc.). The common electrode CE may further include a transparent metal oxide layer disposed on the material layer having the small work function.

Although not illustrated, the common electrode CE may include a capping layer positioned on the transparent conductive metal layer. The capping layer may serve to protect the transparent conductive metal layer. That is, for example, the common electrode CE may be a single film including a conductive metal layer or may be a multilayer film including the conductive metal layer and the capping layer.

The display device 1 may include the hydrogen donor layer 330 positioned on the common electrode CE. As described herein, the hydrogen donor layer 330 may be deposited on the second base substrate 310, and the hydrogen donor layer 330 may be bonded to the first substrate 10 via the sealing part 50 through a subsequent process.

In some embodiments, the hydrogen donor layer 330 may be positioned such that the hydrogen donor layer 330 overlaps the non-emission area BA and the emission areas EA1, EA2, and EA3. In other words, the hydrogen donor layer 330 may be formed as a layer connected to overlap the non-emission area BA and the emission areas EA1, EA2, and EA3. The hydrogen donor layer 330 may be a single film or a multilayer film in which several inorganic insulating materials are stacked.

The hydrogen donor layer 330 may be positioned between the second base substrate 310 and the common electrode CE such that the hydrogen donor layer 330 overlaps the non-emission area BA. In other words, the hydrogen donor layer 330 may be in contact with the common electrode CE such that the hydrogen donor layer 330 overlaps the non-emission area BA. In one or more embodiments, the hydrogen donor layer 330 may be positioned such that the hydrogen donor layer 330 overlaps the light emitting elements ED1, ED2, and ED3 by overlapping the emission areas EA1, EA2, and EA3. In some aspects, the hydrogen donor layer 330 may be positioned such that the hydrogen donor layer 330 overlaps the emission areas EA1, EA2, and EA3 and is spaced apart (e.g., in the Z-axis direction) from the common electrode CE. Accordingly, for example, the spaces SA may be defined between the hydrogen donor layer 330 and the common electrode CE such that the spaces SA overlap the emission areas EA1, EA2, and EA3.

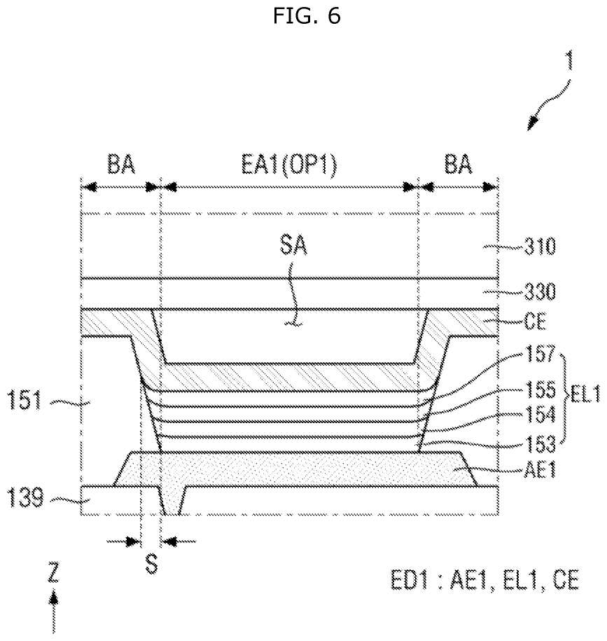

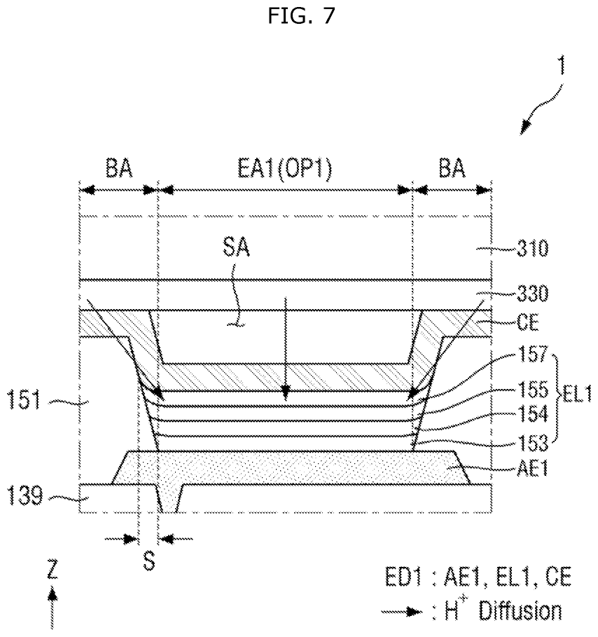

FIG. 6 is an enlarged cross-sectional view of a first emission area of the display device of FIG. 5 in accordance with one or more embodiments of the present disclosure. FIG. 7 is a cross-sectional view illustrating a hydrogen (H) movement path of the display device of FIG. 6 in accordance with one or more embodiments of the present disclosure.

Referring to FIG. 6, the first light emitting structure EL1 of the display device 1 may include a hole injection layer 153, a hole transport layer 154, a quantum dot light emitting layer 155, and an electron transport layer 157.

With reference to FIG. 6, the hole injection layer 153 may be disposed on the pixel electrode AE1. The hole injection layer 153 may serve to facilitate injection of holes from the pixel electrode AE1 into the quantum dot light emitting layer 155. Multiple hole injection layers 153 may be disposed on the pixel electrodes AE1, AE2, and AE3, respectively. The hole injection layers 153 may serve to facilitate injection of holes from the pixel electrodes AE1, AE2, and AE3 into the quantum dot light emitting layers 155. In some aspects, although described as multiple hole injection layers 153, it is to be understood that the examples described herein may refer to a single hole injection layer 153 in which different portions of the hole injection layer 153 are respectively disposed on the pixel electrodes AE1, AE2, and AE3.

As an example, the hole injection layer 153 may include a phthalocyanine compound such as, for example, copper phthalocyanine, N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine (m-MTDATA), 4,4′4″-tris(N,N-diphenylamino) triphenylamine (TDATA), 4,4′,4″-tris {N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenylbenzidine (NPD), polyether ketone containing triphenylamine (TPAPEK), 4-isopropyl-4′-methyldiphenyliodonium [tetrakis(pentafluorophenyl) borate], dipyrazino [2,3-f: 2′,3′-h]quinoxaline-2,3,6,7,10,11-hexacarbonitrile (HAT-CN), or the like.

The hole transport layers 154 may be disposed on the hole injection layers 153. The hole transport layers 154 may serve to facilitate transport of the holes from the pixel electrodes AE1, AE2, and AE3 into the quantum dot light emitting layers 155. The hole transport layer 154 may include carbazole-based derivatives such as, for example, N-phenylcarbazole and polyvinylcarbazole, fluorene-based derivatives, triphenylamine-based derivatives such as, for example, N,N′-bis(3-methylphenyl)-N,N′-diphenyl-[1,1-biphenyl]-4,4′-diamine (TPD) and 4,4′,4″-tris(N-carbazolyl) triphenylamine (TCTA), (NPD), 4,4′-cyclohexylidene N,N′-di(naphthalene-1-yl)-N,N′-diphenyl-benzidine bis [N,N-bis(4-methylphenyl)benzenamine](TAPC), 4,4′-bis [N,N′-(3-tolyl)amino]-3,3′-dimethylbiphenyl (HMTPD), 1,3-bis(N-carbazolyl) benzene (mCP), or the like.

The quantum dot light emitting layer 155 may be disposed on the hole transport layer 154. The quantum dot light emitting layer 155 may include a plurality of quantum dots.

The quantum dots may adjust a color of emitted light according to particle sizes. Accordingly, for example, the quantum dots may have various emission colors such as, for example, blue, red, and green. As the particle size of the quantum dot becomes smaller, the quantum dot may emit light of a shorter wavelength region. For example, among quantum dots having the same core, the particle size of a quantum dot emitting green light may be smaller than the particle size of a quantum dot emitting red light. In one or more embodiments, among quantum dots having the same core, the particle size of a quantum dot emitting blue light may be smaller than the particle size of the quantum dot emitting green light. However, embodiments described herein are not limited thereto, and for examples in which quantum dots have the same core, particle sizes of the quantum dots may be adjusted based on materials of shells, thicknesses of the shells, and the like. In an example in which the quantum dots have various emission colors such as, for example, blue, red, and green, materials of cores of the quantum dots having different emission colors may be different from each other.

Although not illustrated, each quantum dot may include a core layer and a shell layer surrounding the core layer. The quantum dot may further include a ligand bonded to a surface of the shell layer. The quantum dots may be in the form of spherical, pyramidal, multi-arm, or cubic nanoparticles, nanotubes, nanowires, nanofibers, nanoplatelet particles, or the like.

The core layer may be selected from a group II-VI compound, a group III-V compound, a group IV-VI compound, a group IV element, a group IV compound, and combinations thereof.

In an example, the group II-VI compound may be selected from the group consisting of a binary compound selected from the group consisting of CdSe, CdTe, ZnS, ZnSe, ZnTe, ZnO, HgS, HgSe, HgTe, MgSe, MgS, and mixtures thereof; a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

In an example, the group III-V compound may be selected from the group consisting of a binary compound selected from the group consisting of GaN, GaP, GaAs, GaSb, AlN, AIP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AIPAs, AlPSb, InGaP, InAIP, InNP, InNAs, InNSb, InPAs, InPSb, GaAINP, and mixtures thereof; and a quaternary compound selected from the group consisting of GaAINAs, GaAINSb, GaAlPAs, GaAlPSb, GaInNP, GalnNAs, GaInNSb, GalnPAs, GalnPSb, InGaAIP, InAINP, InAINAs, InAINSb, InAIPAs, InAlPSb, and mixtures thereof.

In an example, the group IV-VI compound may be selected from the group consisting of a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof.

In an example, the group IV element may be selected from the group consisting of Si, Ge, and mixtures thereof. The group IV compound may be a binary compound selected from the group consisting of SiC, SiGe, and mixtures thereof.

The shell layer may serve as a protective layer for maintaining semiconductor characteristics by preventing chemical modification of the core layer and/or serve as a charging layer for imparting electrophoretic characteristics to the quantum dot. The shell layer may include metal or non-metal oxide, a semiconductor compound, combinations thereof, or the like. Examples of the metal or non-metal oxide may include a binary compound such as, for example, SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as, for example, MgAl₂O₄, CoFe₂O₄, NiFe₂O₄, or CoMn₂O₄, but the present disclosure is not limited thereto. In one or more embodiments, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb, and the like, but the present disclosure is not limited thereto.

The core layer of the quantum dot described herein may have a diameter of 1 nm to 10 nm, but is not limited thereto. The shell layer may have a thickness of 1 nm to 10 nm, but is not limited thereto. In some aspects, the quantum dots included in the quantum dot light emitting layer 155 may be stacked to form a layer. Specifically, for example, quantum dots included in the quantum dot light emitting layer 155 may be aligned to neighbor to each other to form one layer or may be aligned to form a plurality of layers such as, for example, two layers or three layers. Accordingly, for example, the quantum dot light emitting layer 155 may be a single layer formed of neighboring quantum dots (e.g., neighboring in one or more directions perpendicular to the Z-axis direction) or a plurality of layers, in which each layer is formed of neighboring quantum dots.

The electron transport layer 157 may be disposed on the quantum dot light emitting layer 155. The electron transport layer 157 may serve to facilitate injection and transport of electrons between the common electrode CE and the quantum dot light emitting layer 155 (e.g., from the common electrode CE to the quantum dot light emitting layer 155). The electron transport layer 157 may be formed of a composition for an electron transport layer, and the composition for the electron transport layer may include inorganic particles. The inorganic particles may include a metal oxide. As an example, the electron transport layer 157 of the display device 1 may include ZnMgO or ZnO, but is not limited thereto. In one or more embodiments, the electron transport layer 157 may include a binary compound such as, for example, SiO₂, Al₂O₃, TiO₂, ZnO, MnO, Mn₂O₃, Mn₃O₄, CuO, FeO, Fe₂O₃, Fe₃O₄, CoO, Co₃O₄, NiO, SnO₂, Ta₂O₃, ZrO₂, HfO₂, or Y₂O₃, or a ternary compound such as, for example, ZnMgO, MgAl₂O₄, CoFe₂O₄, NiFe₂O₄, CoMn₂O₄, BaTiO₃, BaZrO₃, or ZrSiO₄.

In some embodiments, the hole injection layer 153, the hole transport layer 154, the quantum dot light emitting layer 155, and the electron transport layer 157 constituting the first light emitting structure EL1 may be manufactured by an inkjet printing process. Accordingly, components of the first light emitting structure EL1 may include inclined parts S, and the inclined parts S may be inclined while climbing along side surfaces of the pixel defining layer 151 at portions where the inclined parts S are in contact with the pixel defining layer 151. In other words, for example, both ends where the first light emitting structure EL1 and the pixel defining layer 151 are in contact with each other may include inclined parts S, and the inclined parts S may be inclined while climbing in a direction toward the second base substrate 310. That is, for example, the first light emitting structure EL1 may be formed in a U shape in which both ends are obliquely inclined. As an example in which the first light emitting structure EL1 is manufactured by an inkjet printing process, both ends of the first light emitting structure EL1 include the inclined parts S.

In some embodiments, the hydrogen donor layer 330 may include an inorganic insulating material having a high content of hydrogen (H). In an example, the content of hydrogen (H) in the hydrogen donor layer 330 may be 1.0E+20 molecules/cm³ or more when measured by thermal desorption spectroscopy (TDS). The expression “hydrogen (H)” as used herein may include both hydrogen ions (H⁺) and hydrogen molecules (H₂).

The content of hydrogen (H) in the hydrogen donor layer 330 may be determined by a ratio of compounds including hydrogen (H) within the hydrogen donor layer 330. Specifically, for example, in accordance with one or more embodiments of the present disclosure, the hydrogen donor layer 330 may be manufactured by a plasma enhanced chemical vapor deposition (PECVD) process, and the content of hydrogen (H) in the hydrogen donor layer 330 may be adjusted by changing a composition ratio of a source gas and a deposition process condition.

As an example, when the hydrogen donor layer 330 is formed of silicon nitride (Si₃N₄), a source gas of the silicon nitride (Si₃N₄) may be formed of a combination of silane (SiH₄) and ammonia (NH₃). In one or more embodiments, a hydrogen molecular (H₂) gas may be included in a process of forming the silicon nitride (Si₃N₄). Accordingly, for example, the hydrogen donor layer 330 may include a structure in which hydrogen (H) is bonded to silicon (Si), a structure in which hydrogen (H) is bonded to nitrogen (N), or both of the structures, in addition to the silicon nitride (Si₃N₄). The above-described example is an example in which the hydrogen donor layer 330 is formed of the silicon nitride (Si₃N₄). In another example, when the hydrogen donor layer 330 includes silicon oxide (SiO₂) and silicon oxynitride (Si₂N₂O), a structure in which hydrogen (H) is bonded to oxygen (O) may also be included in the hydrogen donor layer 330. Therefore, for example, the content of hydrogen (H) in the hydrogen donor layer 330 may be determined according to contents of a silicon-hydrogen (Si—H) bond, a nitrogen-hydrogen bond (N—H), and an oxygen-hydrogen bond (O—H).

Hydrogen (H) included in the hydrogen donor layer 330 may react with a metal oxide included in the light emitting structures EL1, EL2, and EL3 within the display device 1. Hydrogen (H) included in the hydrogen donor layer 330 may serve to increase luminous efficiency by removing an oxygen vacancy phenomenon of the metal oxide included in the light emitting structures EL1, EL2, and EL3, which may improve current characteristics of the display device 1.

As an example, hydrogen (H) included in the hydrogen donor layer 330 may react with zinc magnesium oxide (ZnMgO) or zinc oxide (ZnO) included in the electron transport layer 157, which may improve current injection characteristics of the electron transport layer 157.

Referring to FIG. 7, hydrogen (H) included in the hydrogen donor layer 330 may be diffused within the display device 1 in the direction of the illustrated arrow. That is, for example, hydrogen (H) included in the hydrogen donor layer 330 may be diffused in the arrow direction to react with the first light emitting structure EL1.

In some embodiments, when the hydrogen donor layer 330 includes hydrogen (H) of which a content is 1.0E+20 molecules/cm³ or more when measured by the thermal desorption spectroscopy (TDS), hydrogen (H) of the hydrogen donor layer 330 may be diffused inside the display device 1 without a separate process.

As illustrated in FIG. 7, hydrogen (H) of the hydrogen donor layer 330 may be diffused through the space SA, and the hydrogen (H) may also pass through the common electrode CE and the pixel defining layer 151 and be then diffused. It has been illustrated and described in the example of FIG. 7 that hydrogen (H) of the hydrogen donor layer 330 is diffused into the electron transport layer 157, but the present disclosure is not limited thereto. For example, Hydrogen (H) included in the hydrogen donor layer 330 may pass through the common electrode CE and the pixel defining layer 151 and be then diffused into the hole injection layer 153, the hole transport layer 154, and the quantum dot light emitting layer 155 that are included in the first light emitting structure EL1. For convenience of explanation, the first emission area EA1 has been illustrated and described. For example, with reference to FIG. 7, aspects of hydrogen donor layer 330 with reference to the first emission area EA1 have been illustrated and described. However, aspects of the present disclosure are not limited thereto, and respective hydrogen donor layers 330 overlapping the emission areas EA1, EA2, and EA3 and the light emitting elements ED1, ED2, and ED3 may have the same features and structure.

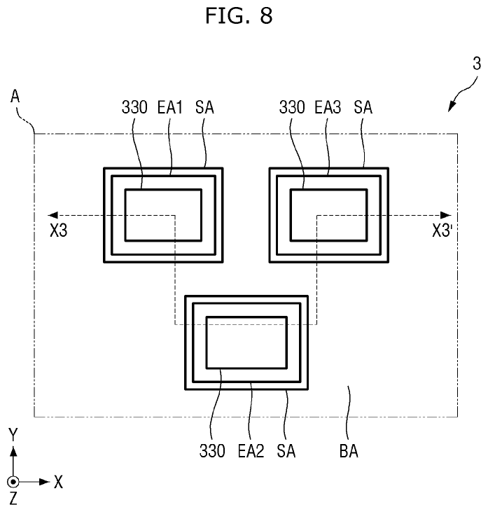

FIG. 8 is an enlarged plan view of area ‘A’ of FIG. 2 according to another embodiment. A display device 3 in accordance with one or more embodiments of the present disclosure is described with reference to FIG. 8. The display device 3 includes aspects of display device 1 described herein, and repeated descriptions of like elements are omitted for brevity.

Referring to FIG. 8, in a plan view, the display device 3 is different from the display device 1 described herein in that hydrogen donor layers 330 are positioned inside the emission areas EA1, EA2, and EA3, and the hydrogen donor layers 330 overlapping the respective emission areas EA1, EA2, and EA3 are positioned to be spaced apart from each other. In other words, for example, the hydrogen donor layers 330 of the display device 3 may be formed or positioned such that the hydrogen donor layers 330 do not overlap the non-emission area BA. The hydrogen donor layers 330 of the display device 3 may be positioned such that the hydrogen donor layers 330 are surrounded by spaces SA overlapping the respective emission areas EA1, EA2, and EA3.

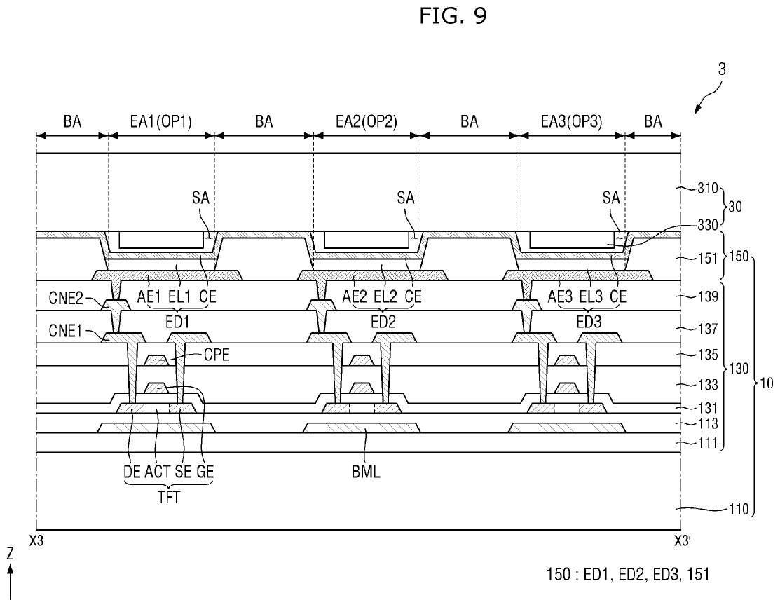

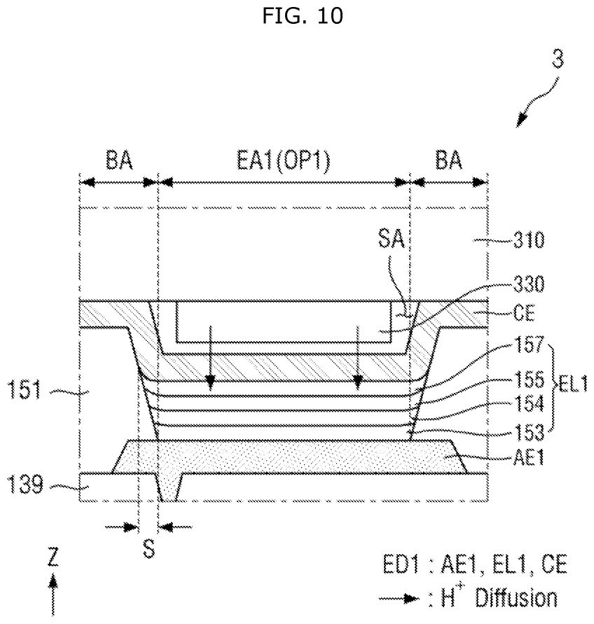

FIG. 9 is a cross-sectional view of the display device 3 taken along line X3-X3′ of FIG. 8. FIG. 10 is an enlarged cross-sectional view of a first emission area of the display device 3 of FIG. 8 in accordance with one or more embodiments of the present disclosure.

In some embodiments, the display device 3 may include spaces SA positioned between the common electrode CE and the second base substrate 310 such that the spaces SA overlap the emission areas EA1, EA2, and EA3. The spaces SA may be caused by bonding between the first substrate 10 and the second substrate 30 of the display device 3. For example, the spaces SA may be formed during a bonding process between the first substrate 10 and the second substrate 30. The spaces SA may be filled with a nitrogen gas (N₂) or air according to the atmosphere of a manufacturing process.

Referring to FIG. 9, the hydrogen donor layers 330 of the display device 3 may be positioned within the spaces SA positioned between the common electrode CE and the second base substrate 310. In other words, for example, the hydrogen donor layers 330 of the display device 3 may be positioned such that the hydrogen donor layers 330 overlap the emission areas EA1, EA2, and EA3. In one or more embodiments, the hydrogen donor layers 330 of the display device 3 may be positioned such that the hydrogen donor layers 330 are not in the non-emission area BA. Therefore, for example, the hydrogen donor layers 330 of the display device 3 are positioned such that the hydrogen donor layers 330 overlap the respective emission areas EA1, EA2, and EA3 and are spaced apart from each other. In some aspects, although described as multiple hydrogen donor layers 330, it is to be understood that the examples described herein may refer to a single hydrogen donor layer 330 in which portions of the hydrogen donor layer 330 overlap respective emission areas EA1, EA2, and EA3 and respective spaces SA.

In some embodiments, the hydrogen donor layers 330 of the display device 3 may be positioned to be spaced apart from the common electrode CE. However, in one or more additional and/or alternative embodiments, in a process of bonding the first substrate 10 and the second substrate 30 to each other, portions of the hydrogen donor layers 330 may be in contact with the common electrode CE.

In some embodiments, the second base substrate 310 of the display device 3 may be in contact with the common electrode CE in the non-emission area BA. In other words, for example, the hydrogen donor layers 330 may be positioned such that the hydrogen donor layers 330 are not between the second base substrate 310 and the common electrode CE of the display device 3, and the hydrogen donor layer 330 may overlap the non-emission area BA.

Referring to FIG. 10, hydrogen (H) included in the hydrogen donor layer 330 of the display device 3 may be diffused in in the direction of the illustrated arrow. As described herein, hydrogen (H) included in the hydrogen donor layer 330 may include both hydrogen ions (H⁺) and hydrogen molecules (H₂).

As described herein, hydrogen (H) included in the hydrogen donor layer 330 of the display device 3 may move to the first light emitting structure EL1, which may improve current injection characteristics of the first light emitting structure EL1. That is, hydrogen (H) included in the hydrogen donor layer 330 may serve to increase efficiency of the display device 3. For convenience of explanation, the first emission area EA1 of the display device 3 has been illustrated and described. For example, with reference to FIG. 10, aspects of hydrogen donor layer 330 with reference to the first emission area EA1 have been illustrated and described. However, aspects of the present disclosure are not limited thereto, and the respective hydrogen donor layers 330 overlapping the emission areas EA1, EA2, and EA3 of the display device 3 and the light emitting elements ED1, ED2, and ED3 may have the same features and structure. Other common descriptions will be omitted. For example, repeated descriptions of some like elements are omitted for brevity.

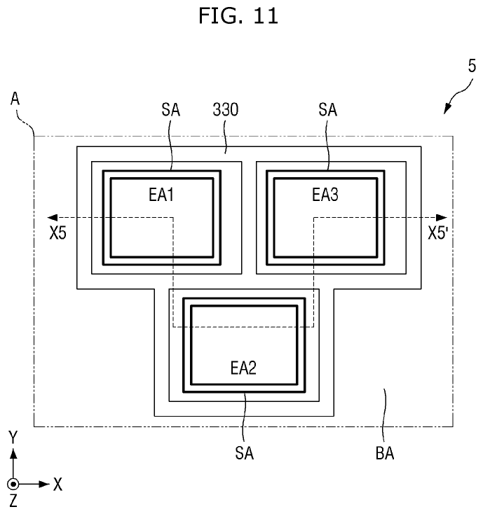

FIG. 11 is an enlarged plan view of area ‘A’ of FIG. 2 according to still another embodiment. A display device 5 in accordance with one or more embodiments of the present disclosure is described with reference to FIG. 11. The display device 5 includes aspects of display device 1 or display device 3 described herein, and repeated descriptions of like elements are omitted for brevity.

Referring to FIG. 11, in a plan view, the display device 5 is different from the display devices 1 and 3 described herein in that hydrogen donor layers 330 are positioned to overlap the non-emission area BA and are positioned to surround the respective emission areas EA1, EA2, and EA3. In other words, for example, the hydrogen donor layers 330 of the display device 5 may be formed or positioned such that the hydrogen donor layers 330 surround spaces SA overlapping the respective emission areas EA1, EA2, and EA3. The hydrogen donor layers 330 of the display device 5 may be positioned to surround the respective emission areas EA1, EA2, and EA3 and may be connected to each other.

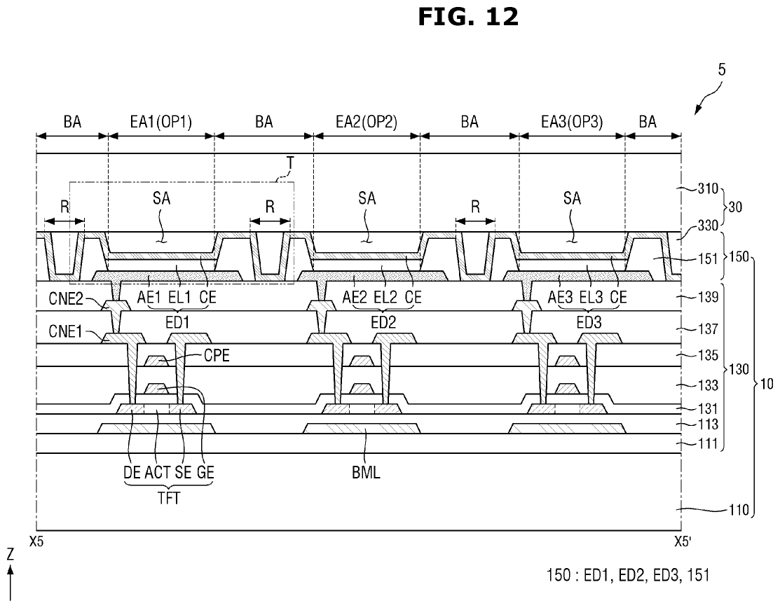

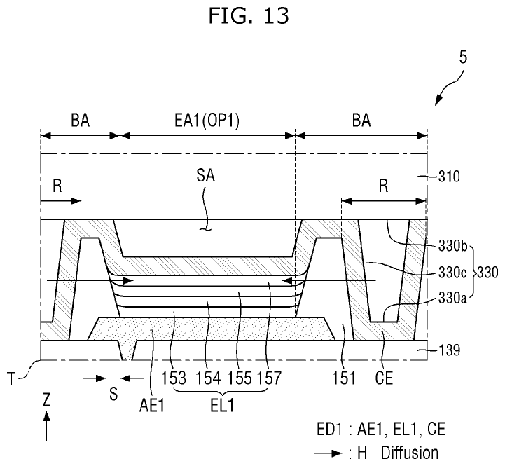

FIG. 12 is a cross-sectional view of the display device 5 taken along line X5-X5′ of FIG. 11. FIG. 13 is an enlarged cross-sectional view of a first emission area of the display device 5 of FIG. 12 in accordance with one or more embodiments of the present disclosure.

Referring to FIG. 12, a first substrate 10 included in the display device 5 is different from the first substrates 10 according to other embodiments in that a pixel defining layer 151 includes recessed parts R. Specifically, the pixel defining layer 151 of the display device 5 may include recessed parts R at a central portion thereof. As an example, the recessed part R of the pixel defining layer 151 may be recessed according to an inverted trapezoidal shape (or an inverted tapered shape) in which a width of a surface (e.g., lower surface) of the inverted trapezoidal shape facing the first base substrate 110 is smaller than a width of another surface (e.g., upper surface) of the inverted trapezoidal shape facing the second base substrate 310. In some aspects, the features of the recessed part R may provide support for the common electrode CE to be deposited without being broken in a subsequent process.

In some embodiments, the common electrode CE of the display device 5 may cover the light emitting structures EL1, EL2, and EL3 such that the common electrode CE overlaps the emission areas EA1, EA2, and EA3, and the common electrode CE may be positioned along the recessed parts R of the pixel defining layer 151 such that the common electrode CE overlaps the non-emission area BA. As described herein, the recessed parts R of the pixel defining layer 151 may be recessed according to the inverted trapezoidal shape, and thus, the common electrode CE may be formed without being broken and such that the common electrode CE overlaps the recessed parts R. Expressed another way, the common electrode CE may be a continuously formed layer.

In some embodiments, the hydrogen donor layers 330 of the display device 5 may be positioned such that the hydrogen donor layers 330 overlap the non-emission area BA. The hydrogen donor layers 330 of the display device 5 may overlap the recessed parts R included in the pixel defining layer 151. In other words, for example, the hydrogen donor layers 330 of the display device 5 may be formed or positioned such that the hydrogen donor layers 330 do not overlap the emission areas EA1, EA2, and EA3.

In some embodiments, the second base substrate 310 of the display device 5 may be spaced apart from the common electrode CE, with the spaces SA interposed between the second base substrate 310 and the common electrode CE, such that the second base substrate 310 overlaps the emission areas EA1, EA2, and EA3. In one or more embodiments, (not illustrated), the second base substrate 310 of the display device 5 may be positioned to be in contact with the common electrode CE and such that the second base substrate 310 overlaps the non-emission area BA.

Referring to FIG. 13, the hydrogen donor layer 330 of the display device 5 may include a first surface 330a facing the first base substrate 110, a second surface 330b opposing the first surface 330a (e.g., the second surface 330b faces in a direction toward the first surface 330a), and an inclined surface 330c connecting the first surface 330a and the second surface 330b to each other. A width of the first surface 330a of the hydrogen donor layer 330 may be smaller than a width of the second surface 330b of the hydrogen donor layer 330. That is, for example, the hydrogen donor layer 330 of the display device 5 may have an inverted trapezoidal shape or an inverted tapered shape.

In the example illustrated in FIG. 13, the hydrogen donor layer 330 of the display device 5 is in contact with the common electrode CE. However, embodiments supported by the present disclosure are not limited thereto. For example, in some other embodiments (not illustrated), the hydrogen donor layer 330 of the display device 5 may be positioned to be spaced apart from the common electrode CE with a space interposed between the hydrogen donor layer 330 and the common electrode CE. In one or more embodiments, a portion of the hydrogen donor layer 330 of the display device 5 may be in contact with the common electrode CE and the other portion of the hydrogen donor layer 330 of the display device 5 may be positioned such that the other portion is spaced apart from the common electrode CE.

In some embodiments, the hydrogen donor layer 330 of the display device 5 may overlap the first light emitting structure EL1 in a direction parallel to the first base substrate 110. Accordingly, for example, the hole injection layer 153, the hole transport layer 154, the quantum dot light emitting layer 155, and the electron transport layer 157 included in the first light emitting structure EL1 may also overlap the hydrogen donor layer 330 of the display device 5 in the direction parallel to the first base substrate 110. In some aspects, the inclined part S included in a portion of the first light emitting structure EL1 in contact with the pixel defining layer 151 may also overlap the hydrogen donor layer 330 in the direction parallel to the first base substrate 110.

As illustrated in FIG. 13, hydrogen (H) included in the hydrogen donor layers 330 of the display device 5 may be diffused in the direction of the illustrated arrows. The hydrogen donor layers 330 of the display device 5 are positioned on both sides of the first light emitting structure EL1 in the direction parallel to the first base substrate 110. Accordingly, for example, hydrogen (H) included in the hydrogen donor layers 330 of the display device 5 may be diffused from both sides of the first light emitting structure EL1.

Hydrogen (H) of the hydrogen donor layers 330 may pass through the common electrode CE and the pixel defining layer 151 and be then diffused. As an example, hydrogen (H) included in the hydrogen donor layers 330 of the display device 5 may serve to increase efficiency of the display device 5 by moving to the electron transport layer 157, which may improve current injection characteristics of the electron transport layer 157. For convenience of explanation, the first emission area EA1 of the display device 5 has been illustrated and described. For example, with reference to FIG. 13, aspects of hydrogen donor layer 330 with reference to the first emission area EA1 have been illustrated and described. However, aspects of the present disclosure are not limited thereto, and the hydrogen donor layers 330 overlapping the emission areas EA1, EA2, and EA3 of the display device 5 and the light emitting elements ED1, ED2, and ED3 may have the same features and structure. Other common descriptions will be omitted. For example, repeated descriptions of some like elements are omitted for brevity.

The effects of the disclosure are not restricted to the example effects set forth herein. The above and other effects of the disclosure will become more apparent to one of daily skill in the art to which the disclosure pertains by referencing the claims.

What is claimed is:

1. A display device comprising:
a first substrate comprising an emission area and a non-emission area;
a first pixel electrode positioned on the emission area of the first substrate;
a first light emitting structure positioned on the first pixel electrode and comprising quantum dots;
a pixel defining layer positioned on the non-emission area of the first substrate and positioned on the first pixel electrode;
a common electrode covering the first light emitting structure and the pixel defining layer; and
an encapsulation structure positioned on the common electrode and in contact with the common electrode such that the encapsulation structure overlaps the non-emission area,
wherein the encapsulation structure comprises a second substrate and a hydrogen donor layer positioned between the second substrate and the common electrode, and
the hydrogen donor layer overlaps the emission area and is in contact with the common electrode or is spaced apart from the common electrode with a space interposed between the hydrogen donor layer and the common electrode.

2. The display device of claim 1, wherein:
the hydrogen donor layer comprises a first portion overlapping the non-emission area and a second portion overlapping the emission area, and
the first portion is in contact with the common electrode.

3. The display device of claim 2, wherein the first portion and the second portion of the hydrogen donor layer extend in a direction parallel to the substrate.

4. The display device of claim 3, wherein the hydrogen donor layer comprises at least one of silicon nitride and silicon oxide.

5. The display device of claim 4, wherein the hydrogen donor layer further comprises hydrogen forming any one of a silicon-hydrogen (Si—H) bond, a nitrogen-hydrogen (N—H) bond, and an oxygen-hydrogen (O—H) bond.

6. The display device of claim 1, wherein the space is surrounded by the non-emission area in a plan view.

7. The display device of claim 1, wherein:
the first light emitting structure comprises a quantum dot light emitting layer and an electron transport layer, and
the first light emitting structure comprises an inclined part inclined in a direction toward the common electrode at a portion of the inclined part in contact with the pixel defining layer.

8. The display device of claim 7, wherein the inclined part overlaps the hydrogen donor layer.

9. The display device of claim 8, wherein the electron transport layer comprises zinc oxide.

10. The display device of claim 1, wherein a portion of the second substrate overlapping the non-emission area is in contact with the common electrode.

11. The display device of claim 10, wherein the hydrogen donor layer is positioned within the space.

12. The display device of claim 11, wherein the hydrogen donor layer does not overlap the non-emission area.

13. The display device of claim 10, further comprising:
a second pixel electrode spaced apart from the first pixel electrode with the pixel defining layer interposed between the second pixel electrode spaced and the first pixel electrode;
a second light emitting structure positioned on the second pixel electrode; and
a second hydrogen donor layer positioned on the second light emitting structure,
wherein the hydrogen donor layer overlaps the first light emitting structure, the second hydrogen donor layer overlaps the second light emitting structure, and the hydrogen donor layer and the second hydrogen donor layer are spaced apart from each other.

14. The display device of claim 13, wherein:
the hydrogen donor layer is surrounded by the space in a plan view, and
the second hydrogen donor layer is surrounded by a second space in the plan view.

15. The display device of claim 14, wherein the space overlapping the first light emitting structure and the second space overlapping the second light emitting structure are spaced apart from each other in the plan view.

16. A display device comprising:
a first substrate comprising an emission area and a non-emission area;
a first pixel electrode positioned on the emission area of the first substrate;
a light emitting structure positioned on the first pixel electrode and comprising quantum dots;
a pixel defining layer positioned on the non-emission area of the first substrate and comprising a recessed part;
a common electrode covering the light emitting structure and the pixel defining layer; and
an encapsulation structure positioned on the common electrode and in contact with the common electrode such that the encapsulation structure overlaps the non-emission area,
wherein the encapsulation structure comprises a second substrate and a hydrogen donor layer positioned between the second substrate and the common electrode, and
the hydrogen donor layer overlaps the recessed part of the pixel defining layer.

17. The display device of claim 16, wherein the hydrogen donor layer comprises:
a first surface facing the first substrate; and
a second surface opposing the first surface, and
a width of the second surface is greater than a width of the first surface.

18. The display device of claim 17, wherein a portion of the second substrate overlapping the emission area is spaced apart from the common electrode with a space interposed between the portion of the second substrate and the common electrode.

19. The display device of claim 18, wherein the hydrogen donor layer surrounds the space in a plan view.

20. The display device of claim 19, further comprising:
a second pixel electrode spaced apart from the first pixel electrode with the pixel defining layer interposed between the second pixel electrode and the first pixel electrode; and
a second light emitting structure positioned on the second pixel electrode,
wherein the hydrogen donor layer is positioned between the light emitting structure and the second light emitting structure.
